(19) United States
(12) Patent Application Publication
(10) Pub. No.: US 2009/0079078 A1
(43) Pub. Date: Mar. 26, 2009

(54) Minimization of Interfacial Resitance Across Thermoelectric Devices by Surface Modification of the Thermoelectric Material

(76) Inventors: Rhonda R. Willigan, Manchester, CT (US); Mark Jaworowski, Glastonbury, CT (US)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 11/992,179

(22) PCT Filed: Sep. 19, 2005
(86) PCT No.: PCT/US2005/033550

§ 371 Date: Mar. 18, 2008

(51) Int. Cl. H01L 23/52; H01L 21/4763

(52) U.S. Cl. 257/751; 438/627; 257/E23.141

(57) ABSTRACT

A coating architecture (106, 206, 306) minimizing interfacial resistance across an interface (100, 200, 300) of a metal (104, 204, 304) and a semiconductor including at least two layers (108, 110, 112, 208, 210, 212, 306) intermediate the metal (104, 204, 304) and the semiconductor.

### BACKGROUND OF THE INVENTION

1. Field of the Invention

The present invention relates generally to minimizing interfacial resistance. More particularly, the present invention relates to minimization of interfacial resistance across thermoelectric devices by surface modification of the thermoelectric material.

2. Description of the Related Art

It is well known that HVAC systems utilizing thermoelectric technology, due to low efficiencies, would not be competitive in today's marketplace. Advanced thermodynamic cycles can increase the coefficient of performance (COP) values by a factor of 2, however, it is equally important that parallel efforts are made to minimize the interfacial resistance, contact resistance, and/or parasitic losses throughout the device, but particularly at the thermoelectric element/metal interface. In order to rival vapor compression COP values, interfacial resistance must be minimized even further, preferably to less than or equal to 1×10-5 Ω-cm, and more preferably to 1×10-7 Ω-cm.

Currently, there are several known techniques that minimize interfacial resistance. These consist of (i) electrolytic etching of the metal surface to increase adhesion, (ii) varying the type and/or composition of the solder, (ii) ion-implantation of the semiconducting material to increase carrier density, and (iii) vapor deposition of one or more layers at the metal-semiconductor interface also to increase carrier density. Generally, the focus of prior art methods of minimizing interfacial resistance in thermoelectric devices has focused on components that go into the device, such as solders and brazes, rather than modifying the thermoelectric element itself. Moreover, the prior art coating architecture on top of thermoelectric elements have been single-component only having a thickness of 10 microns and above.

Thus, there is a need to develop a coating architecture system that will modify the thermoelectric element such that the resulting interfacial resistances are in the range of less than or equal to 1×10-5 Ω-cm having a thickness of less than 10 microns.

### SUMMARY OF THE INVENTION

It is an object of the present invention to provide a coating architecture to modify a thermoelectric element in a thermoelectric device that minimizes interfacial resistance.

It is another object of the present invention to provide a coating architecture to modify a thermoelectric element in a thermoelectric device minimizes interfacial resistance to less than or equal to 1×10-5 Ω-cm and, preferably, to less than 1×10-7 Ω-cm.

It is yet another object of the present invention to provide a coating architecture to modify a thermoelectric element that does not degrade or diffuse into the material.

It is still yet another object of the present invention to provide a coating architecture to modify a thermoelectric element that preserves the hardness of the material.

It is a further object of the present invention to provide a coating architecture to modify a thermoelectric element that is not reactive to or miscible with the solder.

It is yet a further object of the present invention to provide a coating architecture to modify a thermoelectric element to have a total thickness, preferably, of less than 10 microns, and more preferably, 4 microns, and still more preferably, less than 1 micron.

To accomplish the foregoing objects and advantages, the present invention, in brief summary, is a coating architecture that will minimize the interfacial resistance across an interface of a metal and a semiconductor including at least two layers intermediate the metal and the semiconductor.

A coating architecture that will minimize the interfacial resistance across an interface of a metal and a semiconductor including at least one layer having a thickness of less than 4 microns is also provided.

The above-described objects and other features and advantages of the present invention are appreciated and understood by those skilled in the art from the following detailed description, drawings, and appended claims.

### BRIEF DESCRIPTION OF THE DRAWINGS

FIG. 1 illustrates a first exemplary embodiment of a coating architecture applied at an interface of a thermoelectric element and a metal;

FIG. 2 illustrates a second exemplary embodiment of a coating architecture applied at an interface of a thermoelectric element and a metal;

FIG. 3 illustrates a third exemplary embodiment of a coating architecture applied at an interface of a thermoelectric element and a metal; and

FIG. 4 illustrates a first exemplary embodiment of a thermoelectric device having a coating architecture in accordance with the present invention.

### DETAILED DESCRIPTION OF THE INVENTION

The present invention provides a coating architecture for minimizing interfacial resistance across a semiconductor and a metal interface by surface modification of the semiconductor. One such semiconductor and metal interface is that found in a thermoelectric device. Preferably, a thermoelectric element and, in particular, a surface of the thermoelectric element is modified with a coating architecture. However, the coating architecture may be useful for any thermoelectric semiconductor, non-thermoelectric semiconductor, or semi-metal and metal interface. For purposes of clarity, the coating architecture of the present invention is described herein for use with a thermoelectric device.

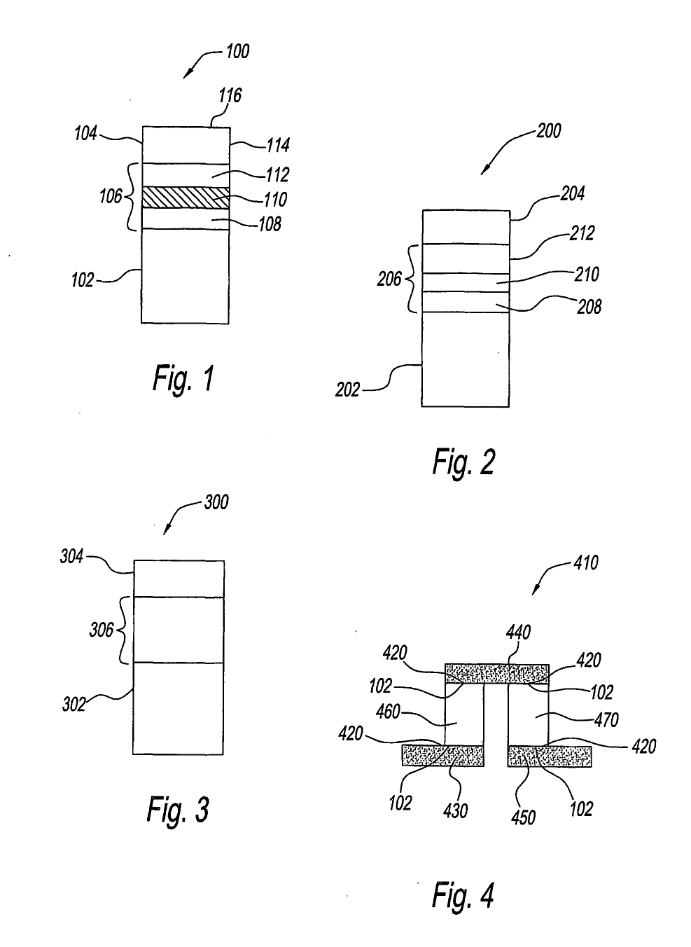

Referring to the drawings and, in particular FIG. 1, an interface of a thermoelectric device generally represented by reference numeral 100 is provided. The interface comprises a thermoelectric element 102 and a metal 104. Intermediate of thermoelectric element 102 and metal 104 is a coating architecture 106. Coating architecture 106 is a multiple component coating architecture having an adhesion layer 108, a diffusion barrier layer 110, and an interfacial resistance reduction layer 112.

On the thermoelectric element 102 is adhesion layer 108. Adhesion layer 108 creates adhesion so that adhesion layer 108, diffusion barrier layer 110, interfacial resistance reduction layer 112, metal 104, and thermoelectric element 102 do not separate. Preferably, the adhesion layer is continuous along thermoelectric element 102.

On adhesion layer 108 opposite thermoelectric element 102 is diffusion barrier layer 110. Diffusion barrier layer 110 prevents interfacial resistance reduction layer 112 from diffusing or mixing with thermoelectric element 102. Thus, diffusion barrier layer acts as a barrier between interfacial resistance reduction layer 112 and thermoelectric element 102. Diffusion barrier layer 110 is, preferably, continuous with adhesion layer 108.

On diffusion barrier layer 110 opposite adhesion layer 108 is interfacial resistance reduction layer 112. Interfacial resistance reduction layer 112 reduces interfacial resistance between thermoelectric element 102 and metal 104. The interfacial resistance reduction layer 112 reduces interfacial resistance by modifying a dopant concentration at a surface or interface 114 between thermoelectric element 102 and a surface 116 of metal 104 facing thermoelectric element 102. In particular, a dopant concentration of a surface of a composite is modified. The composite being a combination of interfacial resistance reduction layer 112, diffusion barrier layer 110, adhesion layer 108 and thermoelectric element 102 resulting in an interfacial resistance, preferably, of less than or equal to 1×10-5 Ω-cm, and more preferably, of less than or equal to 1×10-7 Ω-cm.

Alternatively, interfacial resistance reduction layer 112, diffusion barrier layer 110, and adhesion layer 108 may be in any order between thermoelectric element 102 and metal 104. Furthermore, coating architecture 100 may have any two of interfacial resistance reduction layer 112, diffusion barrier layer 110, or adhesion layer 108 in any order between thermoelectric element 102 and metal 104.

Interfacial resistance reduction layer 112, diffusion barrier layer 110, and adhesion layer 108 may be applied via magnetron sputtering or other applications known in the art for, preferably, a total thickness of less than 10 microns, more preferably 4 microns, and still more preferably, a thickness of less than 1 micron.

The compositions of interfacial resistance reduction layer 112, diffusion barrier layer 110, and adhesion layer 108 are dependent on compositions of metal 104 and thermoelectric element 102. For example, adhesion layer 108 may be a copper or a silver electrodeposit. A surface of thermoelectric element 102 may be textured by standard techniques such as photolithography, mechanical patternation or etching to produce a high specific area surface for enhanced interfacial area and adhesive bond strength. The electrodeposited layer may be modified with mobile additives such as boron or phosphorus that can be controllably and beneficially diffused into thermoelectric element 102. The electrodeposited layer may be deposited by conventional electroplating, electroless plating, pulse plating, or a “superfilling” plating process whereby surface trenches are preferentially filled by a defect-free deposit.

Thermoelectric element 102 is a semiconducting material with a composition of, for example, bismuth telluride Bi₂Te₃, lead telluride PbTe, silicon germanium SiₓGe₁₋ₓ where x is between 0 and 1, or bismuth antimony BiSb.

Metal 104 may be, for example, copper, aluminum or nickel.

Coating architecture 106 may also incorporate transient elements that will diffuse controllably into the depletion zone of the semiconducting material and/or plated materials deposited by, such as, for example, electrochemical plating and/or impurity plating through pulse plating techniques. Coating architecture 106 may also incorporate a doped composition such that once a current is applied to coating architecture 106 and carriers diffuse from metal 104 to thermoelectric element 102, a resulting carrier concentration is optimum and equal to that compared to the metal-semiconductor interface before the current is applied. Furthermore, a doped composition may be incorporated to coating architecture 106 such that once a current is applied and carriers diffuse from thermoelectric element 102 to metal 104, a resulting carrier concentration during operation and under current flow is optimum, which is defined as being equal to that without coating architecture 106 applied and before the current is applied.

Referring now to FIG. 2, a second exemplary embodiment of a coating architecture 206 is illustrated. Again and for purposes of clarity, coating architecture 206 is described herein for use with a thermoelectric device. An interface of a metal and a semiconductor of a thermoelectric device generally represented by reference numeral 200, analogous to interface 100 described above, is provided. The interface comprises a thermoelectric element 202 and a metal 204, analogous to thermoelectric element 102 and a metal 104 described above. Intermediate of thermoelectric element 202 and metal 204 is a coating architecture 206. Coating architecture 206 is a multiple component coating architecture having a first layer 208, a second layer 210, and a third layer 212.

Each of first layer 208, second layer 210, and third layer 212 have a different coefficient of thermal expansion creating a functionally graded interface or a coefficient of thermal expansion gradient. The coefficient of thermal expansion gradient minimizes stress to achieve the optimum ohmic contact between metal 204 and thermoelectric element 202 by minimizing expansion of interface 200 due to thermal cycling and/or large temperature variations and accommodates electrical and mechanical property mismatch between thermoelectric element 202 and metal 204 resulting in an interfacial resistance, preferably, of less than or equal to 1×10-5 Ω-cm, and more preferably, of less than 1×10-7 Ω-cm.

A coefficient of thermal expansion gradient may be created by sputtering or electrochemical plating depending on compositions of first layer 208, second layer 210, third layer 212, thermoelectric element 202, and metal 204. The sputtering or electrochemical plating of each of first layer 208, second layer 210, and third layer 212 controls the potential and/or current density creating the coefficient of thermal expansion gradient.

Furthermore, first layer 208, second layer 210, and third layer 212 have compositions dependent on compositions of metal 204 and thermoelectric element 202. In addition, each of first layer 208, second layer 210, and third layer 212 may also be one of the interfacial resistance reduction layer 112, diffusion barrier layer 110, and adhesion layer 108 as described above.

First layer 208, second layer 210, and third layer 212 may be applied via magnetron sputtering or other known applications known in the art for a thickness, preferably, of less than 10 microns, and more preferably, 4 microns, and still more preferably, less than 1 micron.

Alternately, coating architecture 206 may have up to five layers, and more particularly, two to three layers each having a different coefficient of thermal expansion to create the coefficient of thermal expansion gradient.

Coating architecture 206 may also incorporate transient elements that will diffuse controllably into the depletion zone of the semiconducting material, electrochemical plating, and/or impurity plating through pulse plating techniques.

Thermoelectric element 202, analogous to thermoelectric element 102 described above, is a semi-conductive material with a composition of, for example, bismuth telluride Bi₂Te₃, Lead Telluride PbTe, Silicon Germanium SiₓGe₁₋ₓ where x is between 0 and 1, or bismuth antimony BiSb.

Metal 204, analogous to metal 104 described above, may be, for example, copper, aluminum or nickel.

Coating architecture 206 may also incorporate transient elements that will diffuse controllably into the depletion zone of the semiconducting material and/or plated materials deposited by, such as, for example, electrochemical plating and/or impurity plating through pulse plating techniques. Coating architecture 206 may also incorporate a doped composition such that once a current is applied to coating architecture 206 and carriers diffuse from metal 204 to thermoelectric element 202, a resulting carrier concentration is optimum and equal to that compared to the metal-semiconductor interface before the current is applied. Furthermore, a doped composition may be incorporated to coating architecture 206 such that once a current is applied and carriers diffuse from thermoelectric element 202 to metal 204, a resulting carrier concentration during operation and under current flow is optimum, which is defined as being equal to that without coating architecture 206 applied and before the current is applied.

A third exemplary embodiment of a coating architecture 306 is described. Again, for purposes of clarity, the coating architecture is described herein for use with a thermoelectric device. An interface of a metal and a semiconductor of a thermoelectric device generally represented by reference numeral 300, analogous to interfaces 100 and 200 described above, is provided. The interface comprises a thermoelectric element 302 and a metal 304, analogous to thermoelectric elements 102 and 202 and a metal 104 and 204 described above. Intermediate thermoelectric element 302 and metal 304 is a coating architecture 306.

Coating architecture 306 may be a coating architecture having a deposition of eutectic alloys. Eutectic alloys expand upon solidification, thereby enhancing contact areas after assembly and resulting in an interfacial resistance, preferably, of less than or equal to 1×10-5 Ω-cm, and more preferably, of less than or equal to 1×10-7 Ω-cm.

Alternatively, coating architecture 306 may have multiple components and a single layer. Components can be adhesive components, diffusion barrier components, interfacial resistance reduction components, and any combination thereof. The adhesion components create adhesion so that coating 306, metal 304, and thermoelectric element 302 do not separate. The diffusion barrier components prevent coating 306 from diffusing or mixing with thermoelectric element 302. The interfacial resistance reduction components reduce interfacial resistance between thermoelectric element 302 and metal 304.

Coating architecture 306 has a composition dependent on compositions of metal 304 and thermal electric element 302. In addition, coating architecture 306 may further comprise eutectic alloys deposited in any or all of first layer 208, second layer 210, and third layer 212 described above. The first layer 208, second layer 210, and third layer 212 also may be one of the interfacial resistance reduction layer 112, diffusion barrier layer 110, and adhesion layer 108 also described above.

Moreover, coating architecture 306 may further comprise the eutectic alloys deposited in any or all of the interfacial resistance reduction layer 112, diffusion barrier layer 110, and adhesion layer 108 described above. In particular, the eutectic alloys may be deposited in adhesion layer 108. Eutectic alloys enhance a contact area, which also enhances adhesion to ensure coating architecture 306 adheres to a base compound or thermoelectric element 302.

Coating architecture 306 may be applied via magnetron sputtering or other known applications known in the art, for a thickness, preferably, of less than 10 microns, and more preferably, 4 microns, and still more preferably, less than 1 micron.

Coating architecture 304 may also incorporate transient elements that will diffuse controllably into the depletion zone of the semiconducting material and/or plated materials deposited by, such as, for example, electrochemical plating and/or impurity plating through pulse plating techniques. Coating architecture 306 may also incorporate a doped composition such that once a current is applied to coating architecture 306 and carriers diffuse from metal 304 to thermoelectric element 302, a resulting carrier concentration is optimum and equal to that compared to the metal-semiconductor interface before the current is applied. Furthermore, a doped composition may be incorporated to coating architecture 306 such that once a current is applied and carriers diffuse from thermoelectric element 302 to metal 304, a resulting carrier concentration during operation and under current flow is optimum, which is defined as being equal to that without coating architecture 306 applied and before the current is applied.

Thermoelectric element 302, analogous to thermoelectric element 102 and 202 described above, is a semiconducting material with a composition of, for example, bismuth telluride Bi₂Te₃, Lead Telluride PbTe, Silicon Germanium SiₓGe₁₋ₓ where x is between 0 and 1, or bismuth antimony BiSb.

Metal 304, analogous to metal 104 and 204 described above, may be, for example, copper, aluminum or nickel.

Referring now to FIG. 4, there is illustrated a thermoelectric device generally represented by the reference numeral 410 in accordance with the present invention. In operation, a current is applied to thermoelectric device 410 that passes through interfaces 420 between metal 430, 440 and 450 and thermoelectric elements 460 and 470. Interfacial resistance occurs at interfaces 420. Thus, coating architecture 102 (or 202, or 302) of the present invention is applied at interfaces 420 to minimize interfacial resistance.

Alternatively, coating architecture 102 (or 202, or 302) may be applied to any thermoelectric configuration.

While the present invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A coating architecture for a thermoelectric device having an interface of a metal and a thermoelectric element, the coating architecture comprising:
at least two layers intermediate the metal and the thermoelectric element, wherein the coating architecture reduces interfacial resistance across the interface.

2. The coating architecture of claim 1, wherein said at least two layers comprise at least two of an adhesion layer, a diffusion barrier layer, and an interfacial resistance reduction layer.

3. The coating architecture of claim 2, wherein each of said adhesion layer, said diffusion barrier layer, and said interfacial resistance reduction layer has a different coefficient of thermal expansion forming a coefficient of thermal expansion gradient.

4. The coating architecture of claim 2, wherein at least one of said adhesion layer, said diffusion barrier layer, or said interfacial resistance reduction layer has eutectic alloys deposited therein.

5. The coating architecture of claim 2, wherein said adhesion layer, said diffusion barrier layer, and said interfacial resistance reduction layer have an interfacial resistance of less than or equal to 1×10-5 Ω-cm.

6. The coating architecture of claim 2, wherein said adhesion layer, said diffusion barrier layer, and said interfacial resistance reduction layer, and the thermoelectric element form a composite having a surface, and wherein said surface has a modified dopant concentration compared to the thermoelectric element.

7. The coating architecture of claim 2, wherein said adhesion layer is adjacent said diffusion barrier layer, and wherein said interfacial resistance reduction layer is adjacent said diffusion barrier layer but opposite said adhesion layer.

8. The coating architecture of claim 1, wherein each of said at least two layers has a different coefficient of thermal expansion forming a coefficient of thermal expansion gradient.

9. The coating architecture of claim 8, wherein at least one of said at least two layers has eutectic alloys deposited therein.

10. The coating architecture of claim 8, wherein said at least two layers have an interfacial resistance of less than or equal to 1×10-5 Ω-cm.

11. The coating architecture of claim 1, further comprising a doped composition applied to the interface, wherein the coating architecture has a first carrier concentration with a current applied thereto and carriers diffused into said thermoelectric element from said metal, and wherein said first carrier concentration is equal to an initial carrier concentration absent said electric current applied to the interface.

12. The coating architecture of claim 1, further comprising a doped composition applied to the interface, wherein the coating architecture has a first carrier concentration with a current applied thereto and carriers diffused to the metal from the thermoelectric element, and wherein said first carrier concentration is equal to the interface absent the coating architecture and an initial carrier concentration absent said electric current applied to the interface.

13. A coating architecture for an interface of a metal and a semiconductor, the coating architecture comprising:
at least one layer having a thickness of less than 10 microns, wherein the coating architecture reduces interfacial resistance across the interface.

14. The coating architecture of claim 13, further comprising a doped composition applied to the interface, wherein the coating architecture has a first carrier concentration with a current applied thereto and carriers diffused into the semiconductor from the metal, and wherein said first carrier concentration is equal to an initial carrier concentration absent said electric current applied to the interface.

15. The coating architecture of claim 13, further comprising a doped composition applied to the interface, wherein the coating architecture has a first carrier concentration with a current applied thereto and carriers diffused to the metal from the semiconductor, and wherein said first carrier concentration is equal to the interface absent the coating architecture and an initial carrier concentration absent said electric current applied to the interface.

16. The coating architecture of claim 13, wherein said at least one layer has eutectic alloys deposited therein.

17. The coating architecture of claim 13, wherein the semiconductor is a thermoelectric element, and wherein said thermoelectric element has a surface modified by said at least one layer.

18. The coating architecture of claim 13, wherein said at least one layer is a single layer having an adhesion component, a diffusion barrier component, and an interfacial resistance reduction component.

19. A method of reducing interfacial resistance across an interface of a metal and a semiconductor in a thermoelectric device, the method comprising:
coating the interface with an adhesion layer, a diffusion barrier layer, and an interfacial resistance reduction layer, wherein said adhesion layer, said diffusion barrier layer, and said interfacial resistance reduction layer have different coefficients of thermal expansion and form a coefficient of thermal expansion gradient.

20. (canceled)
